(19) United States
(12) Patent Application Publication
(10) Pub. No.: US 2024/0290862 A1
(43) Pub. Date: Aug. 29, 2024

(54) FERROELECTRIC ZAO(ZIRCONIUM ALUMINIUM OXIDE) COMPOUND, MANUFACTURING METHOD THEREOF, FERROELECTRIC THIN FILM TRANSISTOR INCLUDING THE SAME, AND MANUFACTURING METHOD THEREOF

(71) Applicant: UNIVERSITY-INDUSTRY COOPERATION GROUP OF KYUNG HEE UNIVERSITY, Yongin-si (KR)

(72) Inventors: Jin JANG, Seoul (KR); Islam Md Mobaidul, Seoul (KR)

(73) Assignee: UNIVERSITY-INDUSTRY COOPERATION GROUP OFKYUNG HGEE UNIVERSITY, Yongin-si (KR)

(21) Appl. No.: 18/413,547

(22) Filed: Jan. 16, 2024

(30) Foreign Application Priority Data
Feb. 27, 2023 (KR) `10-2023-0025700

(51) Int. Cl. H01L 29/51; C01G 25/00; H01L 21/28; H01L 29/66; H01L 29/78

(52) U.S. Cl. CPC H01L 29/516; C01G 25/006; H01L 29/40111; H01L 29/66969; H01L 29/78391; B82Y 10/00; B82Y 40/00; C01P 2002/02; C01P 2002/50; C01P 2002/80; C01P 2004/20; C01P 2006/40

(57) ABSTRACT

Disclosed are a ferroelectric zirconium aluminum oxide (ZAO) compound, a method of preparing the same, a ferroelectric thin film transistor including the same and a method of manufacturing the ferroelectric thin film transistor. The ferroelectric zirconium aluminum oxide (ZAO) compound of the present disclosure is characterized by including zirconium and aluminum.

### CROSS-REFERENCE TO RELATED APPLICATION

This application claims priority to Korean Patent Application No. 10-2023-0025700, filed on Feb. 27, 2023 in the Korean Intellectual Property Office, the disclosure of which is incorporated herein by reference.

### BACKGROUND OF THE DISCLOSURE

### Field of the Disclosure

The present disclosure relates to a ferroelectric zirconium aluminum oxide (ZAO) compound, a method of preparing the same, a ferroelectric thin film transistor including the same and a method of manufacturing the ferroelectric thin film transistor, and more particularly a ferroelectric ZAO compound represented by Formula 1, ZrₓAl₁₋ₓO, (where x is 0.1 to 0.9), a method of preparing the same, a ferroelectric thin film transistor including the same and a method of manufacturing the ferroelectric thin film transistor.

### Description of the Related Art

Ferroelectric properties were first discovered in Rochelle salt in 1921, followed by the discovery of perovskite-structured BaTiO₃ (BTO in 1941) and Pb(Zr,Ti)O₃ (PZT in 1952), which became representative ferroelectric materials.

The piezoelectric and pyroelectric properties of ferroelectric materials have been extensively studied and applied to various fields such as sensors and actuators.

The bistable features of ferroelectrics have led to the rapid commercialization of ferroelectric random access memory (FE-RAM), and in back-end-of-the-line (BEOL) ferroelectric capacitors, a ferroelectric capacitor is connected to a drain electrode of a metal-oxide-semiconductor field-effect transistor (MOSFET).

In addition, in the demonstration of ferroelectric field-effect transistors (FE-FETs) in 1970, FE-FETs attracted tremendous attention due to their non-destructive readout properties and energy efficiency.

However, the incompatibility of a ferroelectric material with a perovskite structure in the front end of the FE-FET cannot be realized due to problems such as integrated circuit technology, hydrogen sensitivity, etching, and thickness, so research to improve this is required.

### RELATED ART DOCUMENT

### [Patent Document]

Korea Patent No. 10-2283203, “MANUFACTURING METHOD OF FERROELECTRIC TRANSISTORS AND FERROELECTRIC TRANSISTORS FABRICATED BY USING THE SAME”

### SUMMARY OF THE DISCLOSURE

Therefore, the present disclosure has been made in view of the above problems, and it is an object of the present disclosure to provide a ferroelectric ZAO compound capable of converting an amorphous ZAO compound into a ferroelectric ZAO compound, represented by Formula 1, ZrₓAl₁₋ₓO (where x is 0.1 to 0.9), by a crystalline oxide semiconductor compound containing nanocrystals, a method of preparing the same, a ferroelectric thin film transistor including the same and a method of manufacturing the ferroelectric thin film transistor.

In accordance with an aspect of the present disclosure, the above and other objects can be performed by the provision of a ferroelectric zirconium aluminum oxide (ZAO) compound, including: zirconium; and aluminum,

The ferroelectric ZAO compound may be represented by Formula 1 below:

ZrₓAl₁₋ₓO [Formula 1]
where x is 0.1 to 0.9.

The method may include: growing an amorphous ZAO compound on a substrate; and growing a crystalline oxide semiconductor compound on the amorphous ZAO compound, wherein in the growing of the crystalline oxide semiconductor compound, the amorphous ZAO compound is converted to a ferroelectric ZAO compound by the crystalline oxide semiconductor compound.

The ferroelectric ZAO compound may be represented by Formula 1 below:

ZrₓAl₁₋ₓO [Formula 1]
where x is 0.1 to 0.9

The growing of the crystalline oxide semiconductor compound may be performed by spray pyrolysis.

The crystalline oxide semiconductor compound may include at least one of zinc oxide (ZnO), indium gallium zinc oxide (IGZO), indium oxide (InO), indium gallium oxide (IGO), indium aluminum oxide (IAO), indium zinc oxide (IZO), indium tin oxide (ITO), zinc tin oxide (ZTO), gallium zinc oxide (GZO), hafnium indium zinc oxide (HIZO), indium zinc tin oxide (IZTO) and aluminum zinc tin oxide (AZTO).

In accordance with another aspect of the present disclosure, there is provided a ferroelectric thin film transistor, including: a gate electrode formed on a substrate; a gate insulating layer formed on the gate electrode; an oxide semiconductor layer formed on the gate insulating layer; and a source electrode and drain electrode respectively formed on opposite sides of the oxide semiconductor layer, wherein the gate insulating layer includes the ferroelectric zirconium aluminum oxide (ZAO) compound.

The gate electrode may include a first gate electrode and a second gate electrode.

The gate insulating layer may have a thickness of 30 nm to 60 nm.

The oxide semiconductor layer may contain nanocrystals.

The oxide semiconductor layer may have a thickness of 40 nm to 60 nm.

In accordance with yet another aspect of the present disclosure, there is provided a method of manufacturing a ferroelectric thin film transistor, the method including: forming a gate electrode on a substrate; forming an amorphous gate insulating layer on the gate electrode; forming a crystalline oxide semiconductor layer on the amorphous gate insulating layer; and respectively forming a source electrode and drain electrode on opposite sides of the oxide semiconductor layer, wherein, in the forming of the crystalline oxide semiconductor layer, the amorphous gate insulating layer is converted to a ferroelectric gate insulating layer by the crystalline oxide semiconductor layer.

The ferroelectric gate insulating layer may include a ZAO compound represented by Formula 1 below:

ZrₓAl₁₋ₓO [Formula 1]
where x is 0.1 to 0.9.
the forming of the amorphous gate insulating layer may be performed by spray pyrolysis.
the forming of the crystalline oxide semiconductor layer is performed by spray pyrolysis.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a flowchart illustrating a method of preparing a ferroelectric ZAO compound according to an embodiment of the present disclosure;

FIG. 2 illustrates a schematic diagram of a ferroelectric thin film transistor according to an embodiment of the present disclosure, and FIG. 3 illustrates a schematic diagram of a ferroelectric thin film transistor according to an embodiment of the present disclosure including a stacked gate electrode;

FIG. 4 is a flowchart illustrating a method of manufacturing a ferroelectric thin film transistor according to an embodiment of the present disclosure;

FIG. 5 illustrates graphs of the hysteresis of a ferroelectric thin film transistor according to an embodiment of the present disclosure including a 60 nm ferroelectric gate insulating layer (ZAO), and FIG. 6 illustrates graphs of gate leakage current characteristics;

FIG. 7 illustrates graphs of the hysteresis of a ferroelectric thin film transistor according to an embodiment of the present disclosure including a 50 nm ferroelectric gate insulating layer (ZAO), and FIG. 8 illustrates graphs of gate leakage current characteristics;

FIG. 9 illustrates graphs of the hysteresis of a ferroelectric thin film transistor according to an embodiment of the present disclosure including a 40 nm ferroelectric gate insulating layer (ZAO), and FIG. 10 illustrates graphs of gate leakage current characteristics;

FIG. 11 illustrates PV curve graphs of a ferroelectric thin film transistor according to an embodiment of the present disclosure including a 40 nm ferroelectric gate insulating layer (ZAO),

FIG. 12 illustrates CV curve graphs of a gate insulating layer (ZAO) in a metal-ferroelectric-semiconductor-metal (MFSM) structure,

FIG. 13 illustrates graphs of memory window tuning,

FIG. 14 illustrates gate leakage current characteristic graphs at VDS=0.1V and VGS=±2˜±8V,

FIG. 15 illustrates graphs of temperature-dependent hysteresis,

FIG. 16 illustrates graphs of temperature-dependent gate leakage current characteristics at VDS=0.1V and VGS=±6V,

FIG. 17 illustrates graphs of temperature-dependent output characteristics, and

FIG. 18 illustrates graphs of temperature-dependent output conductance curves;

FIG. 19 illustrates a cross-sectional transmission microscope image of a ferroelectric thin film transistor according to an embodiment of the present disclosure including a ferroelectric gate insulating layer (ZAO),

FIG. 20 illustrates an enlarged transmission microscope image of a gate insulating layer (ZAO) at the position ‘P1’ of ‘a’,

FIG. 21 illustrates an enlarged transmission microscope image of a gate insulating layer (ZAO) at the position ‘P2’ of ‘a’,

FIG. 22 illustrates an STEM measurement result at the position ‘A’ of ‘c’,

FIG. 23 illustrates an FFT measurement result at the position ‘A’ of ‘c’, and

FIG. 24 illustrates the IFFT measurement image and graph of ‘A’ showing IFFT measurement result; and

FIGS. 25 to 29 illustrate graphs of the hysteresis and gate leakage current characteristics of a ferroelectric thin film transistor according to an embodiment of the present disclosure including a ferroelectric gate insulating layer (ZAO) depending upon the molar concentration (Al doping percentage in ZAO) of Al.

### DETAILED DESCRIPTION OF THE DISCLOSURE

The present disclosure will now be described more fully with reference to the accompanying drawings and contents disclosed in the drawings. However, the present disclosure should not be construed as limited to the exemplary embodiments described herein.

The terms used in the present specification are used to explain a specific exemplary embodiment and not to limit the present inventive concept. Thus, the expression of singularity in the present specification includes the expression of plurality unless clearly specified otherwise in context. It will be further understood that the terms “comprise” and/or “comprising”, when used in this specification, specify the presence of stated components and steps, but do not preclude the presence or addition of one or more other components and/or steps.

It should not be understood that arbitrary aspects or designs disclosed in “embodiments”, “examples”, “aspects”, etc. used in the specification are more satisfactory or advantageous than other aspects or designs.

In addition, the expression “or” means “inclusive or” rather than “exclusive or”. That is, unless otherwise mentioned or clearly inferred from context, the expression “x uses a or b” means any one of natural inclusive permutations.

In addition, as used in the description of the disclosure and the appended claims, the singular forms “a”, “an” and “the” are intended to include the plural forms as well, unless context clearly indicates otherwise.

Although terms used in the specification are selected from terms generally used in related technical fields, other terms may be used according to technical development and/or due to change, practices, priorities of technicians, etc. Therefore, it should not be understood that terms used below limit the technical spirit of the present disclosure, and it should be understood that the terms are exemplified to describe embodiments of the present disclosure.

Also, some of the terms used herein may be arbitrarily chosen by the present applicant. In this case, these terms are defined in detail below. Accordingly, the specific terms used herein should be understood based on the unique meanings thereof and the whole context of the present disclosure.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Meanwhile, in the following description of the present disclosure, a detailed description of known functions and configurations incorporated herein will be omitted when it may make the subject matter of the present disclosure unclear. In addition, the terms used in the specification are defined in consideration of functions used in the present disclosure, and can be changed according to the intent or conventionally used methods of clients, operators, and users. Accordingly, definitions of the terms should be understood on the basis of the entire description of the present specification.

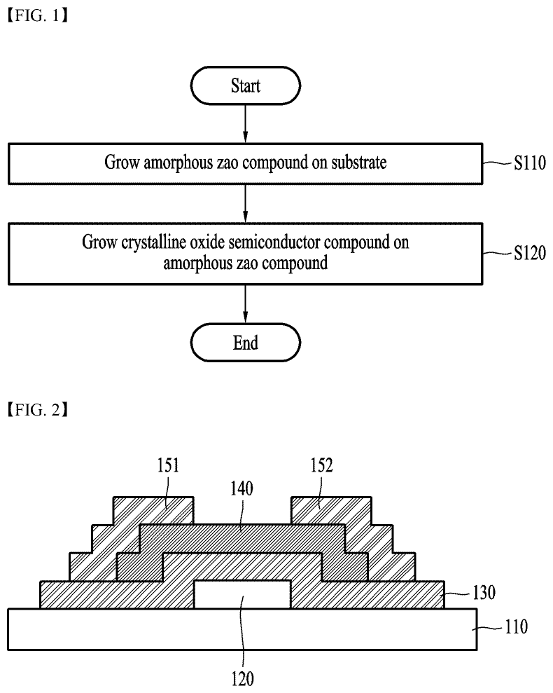

FIG. 1 is a flowchart illustrating a method of preparing a ferroelectric ZAO compound according to an embodiment of the present disclosure.

The ferroelectric ZAO compound according to an embodiment of the present disclosure includes zirconium and aluminum.

Preferably, the ferroelectric ZAO compound according to an embodiment of the present disclosure may be represented by Formula 1 below:

ZrₓAl₁₋ₓO [Formula 1]
where x is 0.1 to 0.9.

The ferroelectricity of the ferroelectric ZAO compound according to an embodiment of the present disclosure may be adjusted depending upon the molar concentration (x) of zirconium (Zr). For example, the molar concentration (x) of zirconium (Zr) may be 0.1 to 0.9, preferably 0.3 to 0.7. More preferably, when the molar concentration (x) of zirconium (Zr) is 0.5 (50%), the best ferroelectric properties can be exhibited.

The molecular weight of the ferroelectric ZAO compound according to an embodiment of the present disclosure may be adjusted depending upon the molar concentration of aluminum (Al), so that electrical characteristics may be controlled.

The molar concentration of aluminum (Al) may be 0.1 (10%) to 0.9 (90%), preferably 0.3(30%) to 0.7(70%). More preferably, when the molar concentration of aluminum (Al) is 0.5 (50%), the best ferroelectric properties can be exhibited.

The ferroelectric ZAO compound according to an embodiment of the present disclosure may have a rhombohedral crystal structure.

A method of preparing the ferroelectric ZAO compound according to an embodiment of the present disclosure includes a step (S110) of growing an amorphous ZAO compound on a substrate and a step (S120) of growing a crystalline oxide semiconductor compound on an amorphous ZAO compound. In the step (S120) of growing a crystalline oxide semiconductor compound on an amorphous ZAO compound, the amorphous ZAO compound is converted into a ferroelectric ZAO compound by the crystalline oxide semiconductor compound.

The method of preparing the ferroelectric ZAO compound according to an embodiment of the present disclosure may include a step (S110) of growing an amorphous ZAO compound on a substrate.

The amorphous ZAO compound may be represented by Formula 2 below:

ZrAlO_{y} [Formula 2]
where y is 2 to 3.

Since the amorphous ZAO compound is composed of ZrO₂ and AL₂O₃, y may be 2 to 3 depending upon the lattice formation of the amorphous ZAO compound.

A non-crystalline ZAO compound may exhibit an amorphous state or good insulating film properties.

Meanwhile, by the method of preparing the ferroelectric ZAO compound according to an embodiment of the present disclosure, an amorphous ZAO compound may be crystallized by applying compressive strain from a crystalline oxide semiconductor compound (e.g., ZnO), thereby being converted into a crystalline ZAO (rhombohedral R3m phase) compound having good ferroelectric properties.

The step (S110) of growing an amorphous ZAO compound may be performed by spray pyrolysis.

Conventionally used spin-coating causes the formation of a film with a non-uniform thickness on a substrate, which may cause uniformity problems between devices.

Meanwhile, may form a film uniformly over a large area by optimizing the deposition conditions including at least one of substrate temperature, a flow rate, a nozzle speed, and a distance between a substrate and a nozzle, and a solution and may form a coffee-ring free film and a high-quality film.

A process temperature of the step (S110) of growing an amorphous ZAO compound may be 360° C.

The process temperature (i.e., deposition temperature) is an important factor in a spray pyrolysis process. By depositing at 360° C., a uniform, coffee ring-free film may be grown. In addition, since an amorphous ZAO compound solution may be completely transformed into amorphous Zr—O—Al trioxide at 360° C., ZAO deposited at 360° C. may exhibit an amorphous state.

Finally, the method of preparing the ferroelectric ZAO compound according to an embodiment of the present disclosure may include a step (S120) of growing a crystalline oxide semiconductor compound on an amorphous ZAO compound.

The crystalline oxide semiconductor compound may include nanocrystals.

The crystalline oxide semiconductor compound may include at least one of zinc oxide (ZnO), indium gallium zinc oxide (IGZO), indium oxide (InO), indium gallium oxide (IGO), indium aluminum oxide (IAO), indium zinc oxide (IZO), indium tin oxide (ITO), zinc tin oxide (ZTO), gallium zinc oxide (GZO), hafnium indium zinc oxide (HIZO), indium zinc tin oxide (IZTO) and aluminum zinc tin oxide (AZTO).

Appropriate strain or stress may stabilize a ferroelectric phase in the crystalline oxide semiconductor compound. For example, the coefficient of thermal expansion (CTE) of ZnO with wurzite phase is 1.57×10⁻⁵ K⁻⁵, which is larger than ZrO (5.57×10⁻⁶ K⁻⁵) and Al₂O₃ (7.5×10⁻⁶ K⁻⁵). Therefore, it may cause compressive strain in the amorphous ZAO compound and stabilize the ferroelectric phase.

Therefore, a crystalline oxide semiconductor compound (e.g., ZnO) with a wurzite structure may be used as the crystalline oxide semiconductor compound.

The step (S120) of growing a crystalline oxide semiconductor compound may be performed by spray pyrolysis.

Conventionally used spin-coating forms a film with non-uniform thickness on a substrate, which may cause uniformity problems between devices.

On the other hand, spray pyrolysis may form a film uniformly over a large area by optimizing deposition conditions, including at least one of substrate temperature, a flow rate, a nozzle speed, and a distance between a substrate and a nozzle, and a solution, and may form a coffee-ring free film and a high-quality film.

A process temperature of the step (S120) of growing a crystalline oxide semiconductor compound may be 350° C.

The process temperature (i.e., deposition temperature) is an important factor in a spray pyrolysis process. By depositing at 350° C., a uniform, coffee ring-free film may be grown.

Since a uniform and coffee ring-free crystalline oxide semiconductor compound was obtained at 350° C., a higher deposition temperature may increase the grain size of the crystalline oxide semiconductor compound and may change electrical characteristics. Accordingly, to maintain a low process temperature, the step (S120) of growing a crystalline oxide semiconductor compound may be performed at 350° C.

In the step (S120) of growing a crystalline oxide semiconductor compound on an amorphous ZAO compound, an amorphous ZAO compound may be converted into a ferroelectric ZAO compound by the crystalline oxide semiconductor compound.

Appropriate strain or stress may stabilize the ferroelectric phase in the crystalline oxide semiconductor compound.

For example, since the coefficient of thermal expansion (CTE) of ZnO with wurzite phase is 1.57×10⁻⁵ K⁻⁵ which is larger than ZrO (5.57×10⁻⁶ K⁻⁵) and Al₂O₃ (7.5×10⁻⁶ K⁻⁵), it may cause compressive strain in the amorphous ZAO compound and stabilize the ferroelectric phase.

The ferroelectric ZAO compound may be represented by Formula 1 below:

ZrₓAl₁₋ₓO [Formula 1]
where x is 0.1 to 0.9.

In addition, the ferroelectric ZAO compound according to an embodiment of the present disclosure may be included in the ferroelectric ZAO film.

Therefore, the ferroelectric ZAO film according to an embodiment of the present disclosure may include the ferroelectric ZAO compound according to an embodiment of the present disclosure.

In addition, in the method of preparing the ferroelectric ZAO compound according to an embodiment of the present disclosure, the amorphous ZAO compound may be an amorphous ZAO film including an amorphous ZAO compound, and the crystalline oxide semiconductor compound may be a crystalline oxide semiconductor film including a crystalline oxide semiconductor compound. Accordingly, the amorphous ZAO film including an amorphous ZAO compound may be converted into a ferroelectric ZAO film including a ferroelectric ZAO compound by the crystalline oxide semiconductor film including a crystalline oxide semiconductor compound.

Therefore, the method of manufacturing the ferroelectric ZAO film according to an embodiment of the present disclosure may include a step of growing an amorphous ZAO compound on a substrate to form an amorphous ZAO film and a step of growing a crystalline oxide semiconductor compound on the amorphous ZAO film to form a crystalline oxide semiconductor film. In the step of growing a crystalline oxide semiconductor compound on the amorphous ZAO film to form a crystalline oxide semiconductor film, the amorphous ZAO film may be converted to a ferroelectric ZAO film by the crystalline oxide semiconductor film.

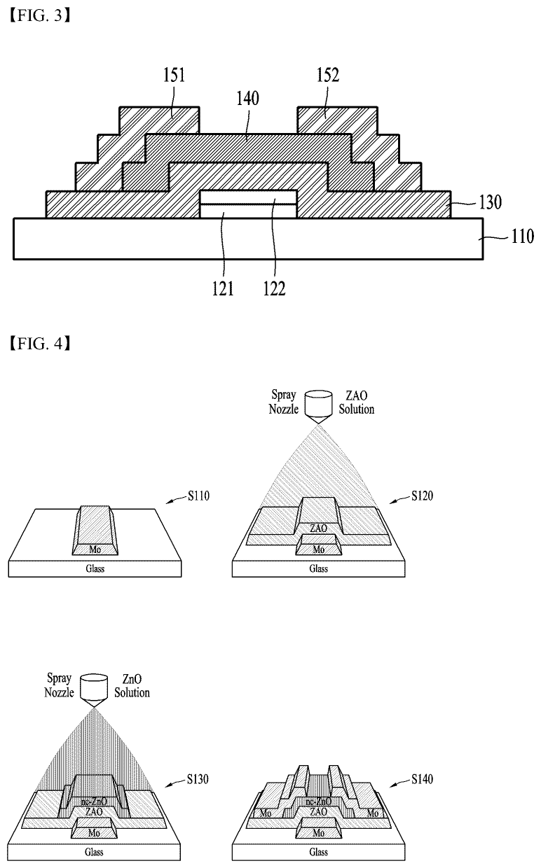

FIG. 2 illustrates a schematic diagram of a ferroelectric thin film transistor according to an embodiment of the present disclosure, and FIG. 3 illustrates a schematic diagram of a ferroelectric thin film transistor according to an embodiment of the present disclosure including a stacked gate electrode.

The ferroelectric thin film transistor according to an embodiment of the present disclosure includes a gate electrode 120 formed on the substrate 110, a gate insulating layer 130 formed on the gate electrode 120, an oxide semiconductor layer 140 formed on the gate insulating layer 130 and a source electrode 151 and drain electrode 152 respectively formed on opposite sides of the oxide semiconductor layer 140.

Accordingly, the gate insulating layer 130 of the ferroelectric thin film transistor according to an embodiment of the present disclosure includes a ferroelectric ZAO compound according to an embodiment of the present disclosure.

Hereinafter, respective components are described in more detail.

The ferroelectric thin film transistor according to an embodiment of the present disclosure includes the gate electrode 120 formed on the substrate 110.

The substrate is a base substrate for forming a ferroelectric thin film transistor. The material of a substrate used in the art is not specifically limited, and may be made of various materials such as, for example, silicone, glass, plastic, quartz or metal foil.

The gate electrode may include metal or metal oxide which is an electrically conductive material. Specifically, the gate electrode may include at least one material of a metal such as a metal such as molybdenum (Mo), aluminum (Al), chromium (Cr), gold (Au), titanium (Ti) or silver (Ag) and a metal oxide such as indium tin oxide (ITO), indium zinc oxide (IZO) or indium tin zinc oxide (ITZO).

The gate electrode 120 may include a first gate electrode 121 and a second gate electrode 122.

The second gate electrode 122 may be formed on the first gate electrode 121 to prevent the first gate electrode 121 from being oxidized during the formation of the gate insulating layer 130.

More particularly, to prevent the oxidization of the first gate electrode 121 and the formation of a dead layer when a gate insulating layer is formed through spray pyrolysis on the first gate electrode 121 at high temperature, a thin second gate electrode 122 may be formed on the first gate electrode 121.

For example, the first gate electrode 121 may include a metal, and the second gate electrode 122 may include a metal oxide.

The thickness of the first gate electrode 121 may be 10 nm or more. For example, the thickness of the first gate electrode 121 may be 50 nm.

Here, the first gate electrode 121 may be used as a main gate electrode.

The ferroelectric thin film transistor according to an embodiment of the present disclosure includes a gate insulating layer 130 formed on the gate electrode 120.

The gate insulating layer 130 includes the ferroelectric ZAO compound according to an embodiment of the present disclosure. Here, descriptions of the same components are omitted.

In addition, an operating voltage width (memory window) may be controlled depending upon the thickness of the gate insulating layer 130. For example, as the thickness of the gate insulating layer 130 increases, an operating voltage width (memory window) may be narrowed, resulting in property decrease.

On the other hand, when the thickness of the gate insulating layer 130 becomes thin, breakdown easily occurs, making it impossible to manufacture a rigid transistor. In particular, when a gate voltage increases, breakdown may easily occur.

The thickness of the gate insulating layer 130 may be 30 nm to 60 nm.

The ferroelectric thin film transistor according to an embodiment of the present disclosure includes an oxide semiconductor layer 140 formed on the gate insulating layer 130.

The oxide semiconductor layer 140 may include nanocrystals.

Therefore, the oxide semiconductor layer 140 may include a crystalline oxide semiconductor compound. Here, the crystalline oxide semiconductor compound may include at least one of zinc oxide (ZnO), indium gallium zinc oxide (IGZO), indium oxide (InO), indium gallium oxide (IGO), indium aluminum oxide (IAO), indium zinc oxide (IZO), indium tin oxide (ITO), zinc tin oxide (ZTO), gallium zinc oxide (GZO), hafnium indium zinc oxide (HIZO), indium zinc tin oxide (IZTO) and aluminum zinc tin oxide (AZTO).

The thickness of the oxide semiconductor layer 140 may be 40 nm to 60 nm.
the thickness of the oxide semiconductor layer 140 is an important factor in inducing appropriate compressive strain in an amorphous ZAO compound.

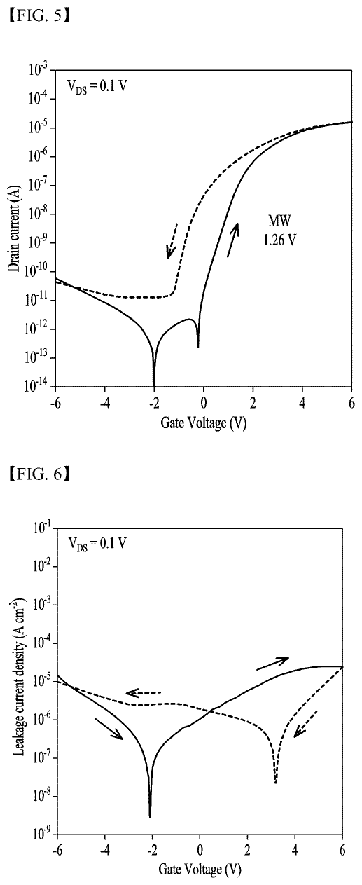

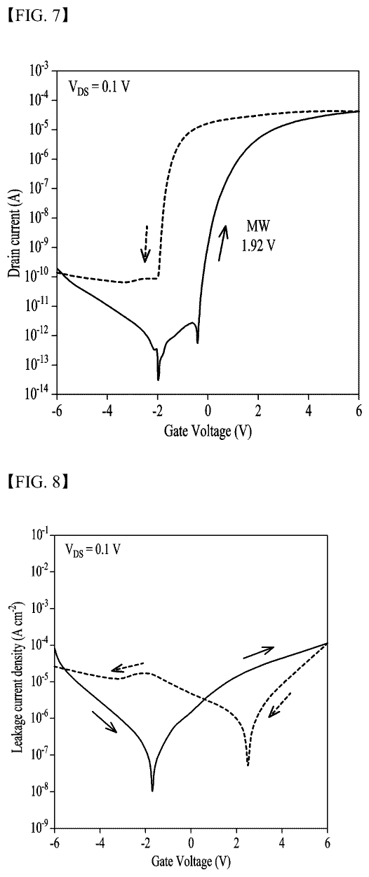

For example, when ZnO is used as a crystalline oxide semiconductor compound, 50 nm ZnO cannot induce appropriate compressive strain in 50 and 60 nm ZAO and may exhibit a low operating voltage width (memory window) of 1.26 and 1.92 V (see FIGS. 5 and 7).

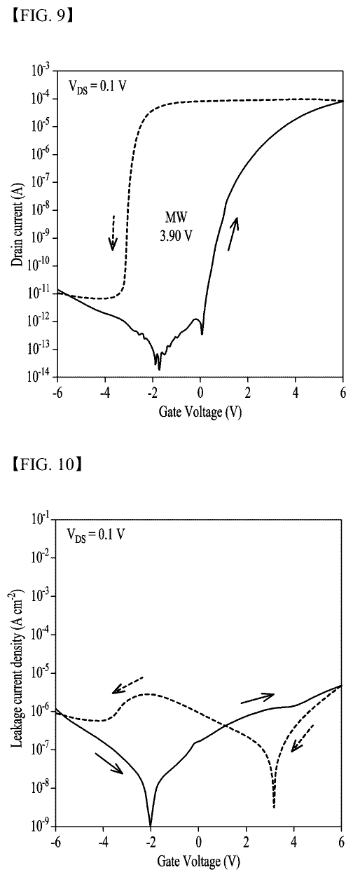

On the other hand, 50 nm ZnO induces appropriate compressive strain in 40 nm ZAO, thereby exhibiting a large operating voltage width (memory window) of 3.9 V and a clear current peak at gate leakage (see FIGS. 9 and 10).

The ferroelectric thin film transistor according to an embodiment of the present disclosure includes a source electrode 151 and drain electrode 152 respectively formed on opposite sides of the oxide semiconductor layer 140.

The thickness of each of the source electrode 151 and the drain electrode 152 may be 40 nm or more to increase conductivity, and even when the thickness of each of the source electrode 151 and the drain electrode 152 exceeds 40 nm, electrical characteristics do not change significantly.

For example, the thickness of each of the source electrode 151 and the drain electrode 152 may be 50 nm.

FIG. 4 is a flowchart illustrating a method of manufacturing a ferroelectric thin film transistor according to an embodiment of the present disclosure.

The method of manufacturing the ferroelectric thin film transistor according to an embodiment of the present disclosure includes the same components as in the ferroelectric ZAO compound according to an embodiment of the present disclosure and the ferroelectric thin film transistor according to an embodiment of the present disclosure, so descriptions of the same components are omitted.

First, the method of manufacturing the ferroelectric thin film transistor according to an embodiment of the present disclosure includes a step (S210) of forming a gate electrode on a substrate.

The gate electrode may be formed by depositing a conductive gate film on a substrate and forming a photoresist pattern on the conductive gate film, followed by selectively etching, i.e., patterning the conductive gate film using a photoresist pattern as a mask.

The gate electrode may be formed to a thickness of 10 nm or more. When the thickness is 10 nm or less, there is a problem in that the resistance of a gate electrode increases.

The gate electrode may include metal or metal oxide which is an electrically conductive material. Specifically, the gate electrode may include at least one material of a metal such as molybdenum (Mo), aluminum (Al), chromium (Cr), gold (Au), titanium (Ti) or silver (Ag) and a metal oxide such as indium tin oxide (ITO), indium zinc oxide (IZO) or indium tin zinc oxide (ITZO).

The gate electrode may be formed by a deposition process such as chemical vapor deposition, physical vapor deposition or atomic layer deposition.

According to an embodiment, a step (S110) of forming a gate electrode on the substrate may include a step (S211) of forming a first gate electrode and a step (S212) of forming a second gate electrode on the first gate electrode.

The first gate electrode may include a metal, and the second gate electrode may include a metal oxide.

Next, the method of manufacturing the ferroelectric thin film transistor according to an embodiment of the present disclosure includes a step (S220) of forming an amorphous gate insulating layer on the gate electrode.

The amorphous gate insulating layer may include an amorphous ZAO compound.

The amorphous ZAO compound may be represented by Formula 2 below:

ZrAlO_{y} [Formula 2]
where y is 2 to 3.

Since the amorphous ZAO compound is composed of ZrO₂ and AL₂O₃, y may be in range of 2 to 3 depending upon the lattice formation of amorphous ZAO compound.

The step (S220) of forming an amorphous gate insulating layer may be performed by spray pyrolysis.

A process temperature of the step (S220) of forming an amorphous gate insulating layer may be 360° C.

Next, the method of manufacturing the ferroelectric thin film transistor according to an embodiment of the present disclosure may include a step (S230) of forming a crystalline oxide semiconductor layer on the amorphous gate insulating layer.

The crystalline oxide semiconductor layer may include nanocrystals.

The crystalline oxide semiconductor layer may be formed by depositing a crystalline oxide semiconductor on an amorphous gate insulating layer and forming a photoresist pattern on the crystalline oxide semiconductor, followed by patterning the crystalline oxide semiconductor using a photoresist pattern as a mask. Here, a crystalline oxide semiconductor layer may be formed in the form of multiple island patterns of various shapes by implementing the photoresist pattern in various shapes.

The step (S230) of forming a crystalline oxide semiconductor layer may be performed by spray pyrolysis. Preferably, spray pyrolysis may be used when a crystalline oxide semiconductor is deposited on the amorphous gate insulating layer.

A process temperature of the step (S230) of forming a crystalline oxide semiconductor layer may be 350° C.

Therefore, by the method of manufacturing the ferroelectric thin film transistor according to an embodiment of the present disclosure, the amorphous gate insulating layer may be converted to a ferroelectric gate insulating layer by growing a crystalline oxide semiconductor layer on the amorphous gate insulating layer.

Appropriate strain or stress may stabilize the ferroelectric phase in the crystalline oxide semiconductor compound. For example, since the coefficient of thermal expansion (CTE) of ZnO with wurzite phase is 1.57×10⁻⁵ K⁻⁵ which is larger than ZrO (5.57×10⁻⁶ K⁻⁵) and Al₂O₃ (7.5×10⁻⁶ K⁻⁵), it may induce the compressive strain in the amorphous ZAO compound and stabilize the ferroelectric phase.

Finally, the method of manufacturing the ferroelectric thin film transistor according to an embodiment of the present disclosure may include a step (S240) of respectively forming a source electrode and drain electrode on opposite sides of the oxide semiconductor layer.

The source electrode and a drain electrode may be formed on the substrate on which an oxide semiconductor layer has been formed. Specifically, the source electrode and the drain electrode may be formed to be spaced apart from each other on the substrate on which the oxide semiconductor layer has been formed.

The source electrode and the drain electrode may include a metal or a metal oxide. Specifically, the source electrode and the drain electrode may include at least one material of a metal such as molybdenum (Mo), aluminum (Al), chromium (Cr), gold (Au), titanium (Ti) or silver (Ag) and a metal oxide such as indium tin oxide (ITO), indium zinc oxide (IZO) or indium tin zinc oxide (ITZO).

Each of the source electrode and the drain electrode may be formed by depositing a source/drain conductive film on the oxide semiconductor layer and forming a photoresist pattern on the source/drain conductive film, followed by patterning the source/drain conductive film using a photoresist pattern as a mask. Here, a source electrode and drain electrode with various shapes may be formed by implementing the photoresist pattern in various shapes.

More particularly, the source electrode and the drain electrode may be formed through a photolithography process after depositing a source/drain conductive film through sputtering.

### PREPARATION EXAMPLE

### (Synthesis of Precursor Solution)

ZAO and ZnO solutions were prepared using zirconium acetylacetonate (Zr(C₅H₇O₂)₄) (Alfa Aesar), aluminum acetylacetonate (Al(C₅H₇O₂)₃) (Sigma Aldrich) and zinc acetate dihydrate (Zn(CH₃COO)₂·2H₂O) (Sigma Aldrich) precursor.

0.15 M ZAO precursor solution was synthesized by dissolving Zr and Al in a 1:1 molar ratio in a solvent mixture of N,N-dimethylformamide and methyl alcohol mixed in a ratio of 7:3, and, to obtain a transparent and uniform precursor solution, the ZAO solution was stirred on a preheated magnetic stirrer at 70° C. for at least 6 hours.

0.2 M ZnO precursor solution was synthesized using 2-methoxyethanol solvent and stirred for 6 hours on a magnetic stirrer at room temperature.

Both the solutions were filtered using a 0.45 μm polytetrafluoroethylene filter before spray coating.

### (Deposition of Gate Oxide)

A ZAO thin film was grown by spray pyrolysis at a substrate temperature of 360° C.

The flow rate of a precursor solution was about 0.5 ml min⁻¹. The nozzle scan speed was 7 cm s⁻¹, and the vertical distance between the nozzle and the substrate was 11.5 cm.

A gate insulating layer was deposited for 12, 10, or 8 cycles to have a thickness of approximately 30, 25, or 20 nm, and then the sample was cured for 3 minutes on a hot plate at the same temperature.

Next, one-scan Ar/O₂ (230 W, 12/20 sccm) plasma treatment was performed on the ZAO film in room-temperature atmosphere.

This process was repeated twice to produce ZAO films with thicknesses of about 60, 50 and 40 nm, and then annealed at 360° C. for 1 hour.

### (Deposition of Oxide Semiconductor)

The ZnO film was deposited at a substrate temperature of 350° C. by spray pyrolysis.

(Ferroelectric thin film transistor)

Inverted staggered ZnO TFTs were fabricated to various FE-ZAO layer thicknesses.

First, a 60 nm molybdenum (Mo) and a 15 nm IZO layer were deposited by sputtering under vacuum on a glass substrate for a gate electrode.

After patterning a gate electrode, a ZAO thin film (60, 50, 40 nm) was deposited by spray pyrolysis, and then a ZnO (50 nm) oxide semiconductor thin film was deposited by spray pyrolysis.

Next, ZnO and ZAO layers were patterned and wet-etched to form active islands and contact holes, respectively.

Next, a 50 nm Mo layer was deposited and patterned by sputtering to form source and drain (S/D) electrodes.

A conventional photolithography process was used to pattern and etch all layers.

FIG. 5 illustrates graphs of the hysteresis of a ferroelectric thin film transistor according to an embodiment of the present disclosure including a 60 nm ferroelectric gate insulating layer (ZAO), and FIG. 6 illustrates graphs of gate leakage current characteristics.

Referring to FIGS. 5 and 6, the hysteresis behavior in a counterclockwise direction is shown, and the leakage current curve has a butterfly shape.

FIG. 7 illustrates graphs of the hysteresis of a ferroelectric thin film transistor according to an embodiment of the present disclosure including a 50 nm ferroelectric gate insulating layer (ZAO), and FIG. 8 illustrates graphs of gate leakage current characteristics.

Referring to FIGS. 7 and 8, the hysteresis behavior in a counterclockwise direction is exhibited, and the leakage current curve has a butterfly shape.

FIG. 9 illustrates graphs of the hysteresis of a ferroelectric thin film transistor according to an embodiment of the present disclosure including a 40 nm ferroelectric gate insulating layer (ZAO), and FIG. 10 illustrates graphs of gate leakage current characteristics.

Referring to FIGS. 9 and 10, the hysteresis behavior in a counterclockwise direction is exhibited, the leakage current curve has a butterfly shape.

Therefore, referring to FIGS. 5 to 10, the hysteresis behavior in a counterclockwise direction, low SS (≈60 mV dec⁻¹) and the leakage current curve with a butterfly shape indicates that the gate insulating layer is a ferroelectric gate insulating layer (ZAO) exhibiting ferroelectric properties.

In Table 1, the results of FIGS. 5 to 10 are shown.

TABLE 1

| | | | | | Saturation | Remanent | Coercive |
|---|---|---|---|---|---|---|---|
| | | Process | | | Polarization, | Polarization, | Electric |
| | Thickness, | Temp. | Ferroelectric | Space | Pₛ , μC | Pᵣ , μC | Field, E_{c} , |
| Material | nm) | ° C.) | Phase) | Group | cm⁻²) | cm⁻²) | MV cm⁻¹) |
| HfO₂* | — | — | Orthorhombic | Pca2₁ | — | 26 | — |
| HfO₂* | — | — | Orthorhombic | Pmn2₁ | — | 28 | — |
| HZO | ≤10 | ≥600 | Orthorhombic | Pca2₁ | — | ≈32 | 0.8-2 |
| Si:HfO₂ | 1.5-15 | 700 | Orthorhombic | Pca2₁ | — | 8-32 | 4-5 |
| Al:HfO₂ | 16 | 800 | Orthorhombic | Pca2₁ | — | 5 | 1.0 |
| Gd:HfO₂ | 27 | 650 | Orthorhombic | Pca2₁ | — | ≈15 | ≈1.9 |
| La:HfO₂ | 10 | 800 | Orthorhombic | Pca2₁ | — | 27 | >1.2 |
| Y:HfO₂ | — | 1600 | Orthorhombic | Pbc2₁ | — | 3 | 4.0 |
| Ca:HfO₂ | 35 | 700 | Orthorhombic | Pca2₁ | — | 10.5 | 2 |
| Sr:HfO₂* | 10 | — | Orthorhombic | Pca2₁ | — | — | — |
| HZO | 9 | 800 | Rhombohedral | R3m | — | 18 | 3.0 |
| ZrO₂ | ≈14 | 600 | Orthorhombic | Pbc2₁ | — | 3.8 | ≈0.5 |
| ZrO₂ | 8 | 700 | Rhombohedral | R3m | 20.2 | — | 1.5 |
| ZAO | 41 | 360 | Rhombohedral | R3m | 18 | 16 | 1.15 |

Referring to Table 1, it can be confirmed that the thickness of the conventional gate insulating layer is 35 nm or less, but the ferroelectric gate insulating layer (ZAO) included in the ferroelectric thin film transistor according to an embodiment of the present disclosure exhibits the best characteristics when the thickness thereof is 41 nm.

More particularly, when the gate insulating layer is thin, breakdown can easily occur, making it difficult to manufacture a rigid transistor. When the gate voltage increases, breakdown may easily occur.

However, since the ferroelectric thin film transistor according to an embodiment of the present disclosure can exhibit excellent electrical characteristics even when the ferroelectric gate insulating layer (ZAO) is thickly formed, both the electrical and physical characteristics of the ferroelectric thin film transistor according to an embodiment of the present disclosure can be improved by forming a thick ferroelectric gate insulating layer (ZAO).

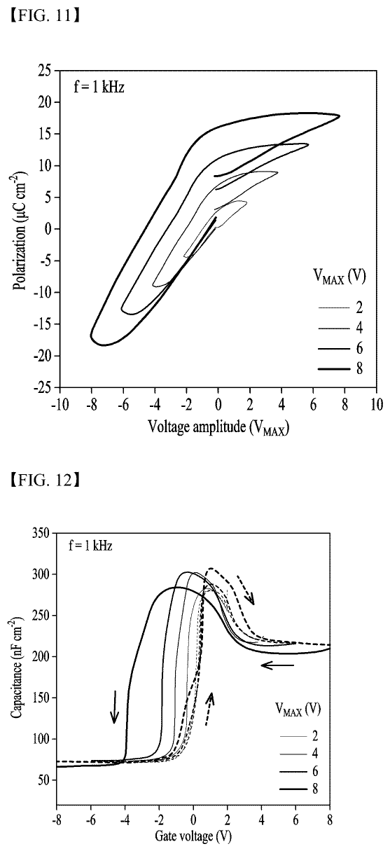

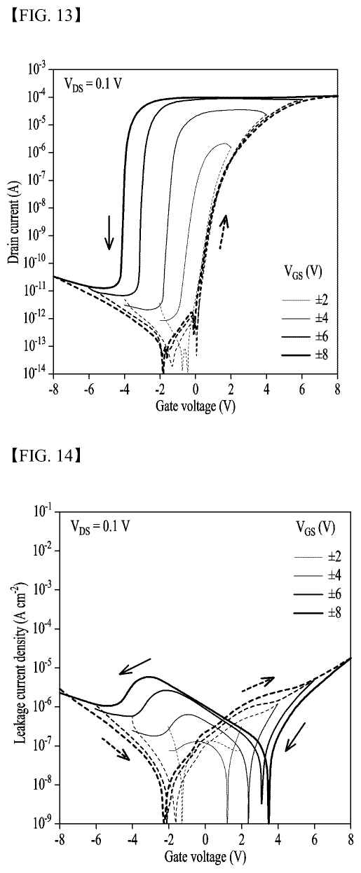

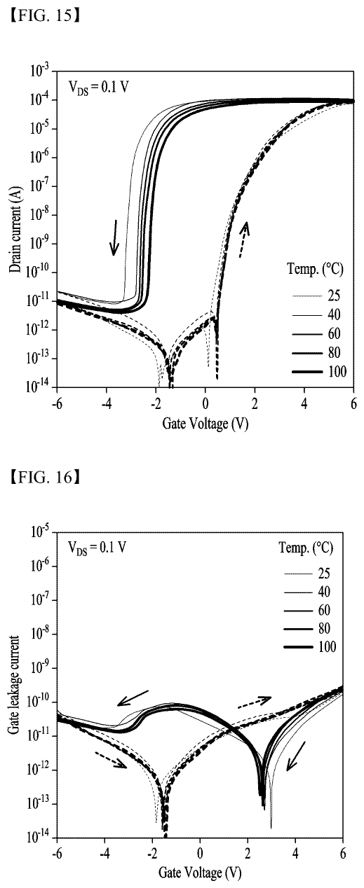

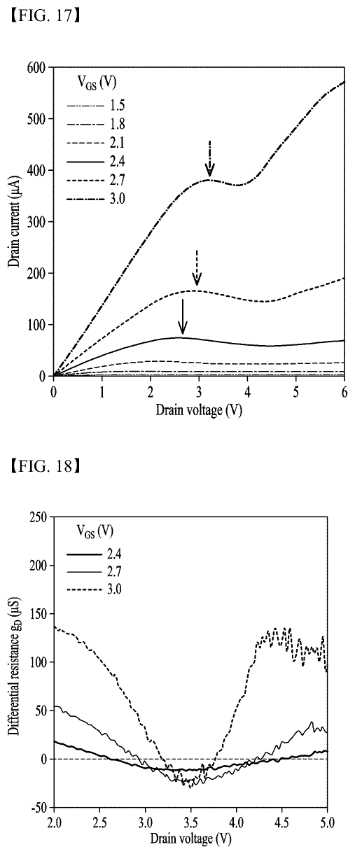

FIG. 11 illustrates PV curve graphs of a ferroelectric thin film transistor according to an embodiment of the present disclosure including a 40 nm ferroelectric gate insulating layer (ZAO), FIG. 12 illustrates CV curve graphs of a gate insulating layer (ZAO) in a metal-ferroelectric-semiconductor-metal (MFSM) structure, FIG. 13 illustrates graphs of memory window tuning, FIG. 14 illustrates gate leakage current characteristic graphs at VDS=0.1V and VGS=±2˜±8V, FIG. 15 illustrates graphs of temperature-dependent hysteresis, FIG. 16 illustrates graphs of temperature-dependent gate leakage current characteristics at VDS=0.1V and VGS=±6V, FIG. 17 illustrates graphs of temperature-dependent output characteristics, and FIG. 18 illustrates graphs of temperature-dependent output conductance curves.

Referring to FIGS. 11 to 18, the P-V and C-V hysteresis characteristics varied the applied sweeping voltage for various maximum amplitudes (VMAX) of 2, 4, 6, and 8 V.

The PV hysteresis loop becomes saturated as VMAX increases, the saturation polarization (Ps), remnant polarization (Pr) and coercive electric field (Ec) of ZAO MFSM capacitor gradually increased as V_{MAX} increases from 2 V to 8 V, and the extracted saturation polarization (Ps) and the remnant polarization (Pr) were similar to those of the ferroelectric capacitor.

In addition, it can be seen that the ferroelectric thin film transistor according to an embodiment of the present disclosure is stable with respect to temperature and has excellent reproducibility and uniformity.

In addition, in NC-FET, NDR occurred due to the drain-coupled negative capacitance effect, which increased VDS and decreased the interface potential between MOS and ferroelectric gate oxide.

Therefore, it can be seen that, as the channel resistance increases and the charge density of the channel decreases, the ZAO gate insulating layer of the ferroelectric thin film transistor according to an embodiment of the present disclosure has ferroelectric characteristics.

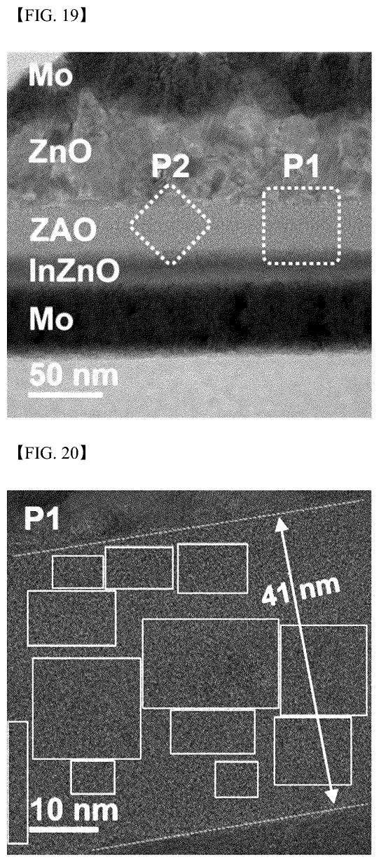

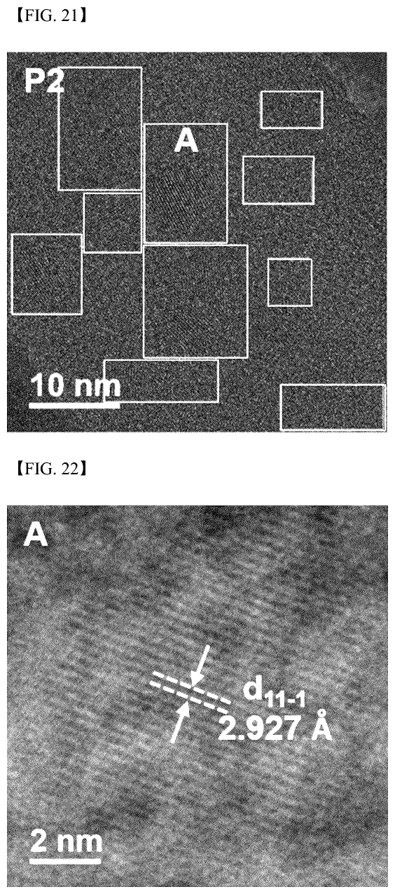

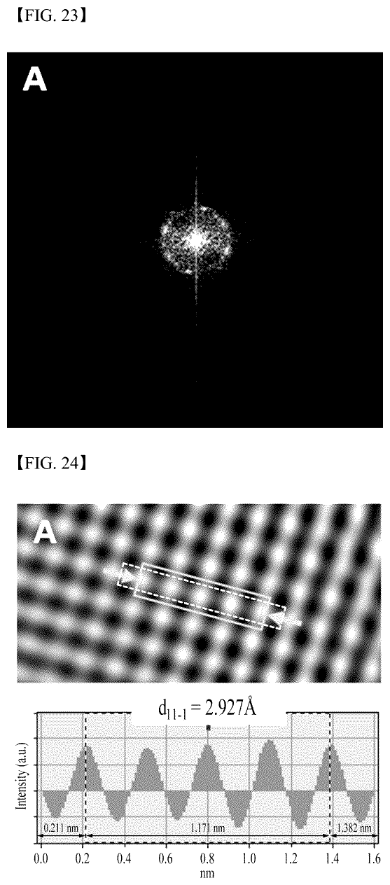

FIG. 19 illustrates a cross-sectional transmission microscope image of a ferroelectric thin film transistor according to an embodiment of the present disclosure including a ferroelectric gate insulating layer (ZAO), FIG. 20 illustrates an enlarged transmission microscope image of a gate insulating layer (ZAO) at the position ‘P1’ of ‘a’, FIG. 21 illustrates an enlarged transmission microscope image of a gate insulating layer (ZAO) at the position ‘P2’ of ‘a’, FIG. 22 illustrates an STEM measurement result at the position ‘A’ of ‘c’, FIG. 23 illustrates an FFT measurement result at the position ‘A’ of ‘c’, and FIG. 24 illustrates the IFFT measurement image and graph of ‘A’ showing IFFT measurement result.

Referring to FIGS. 19 to 24, it can be seen that the ferroelectric characteristics of the gate insulating layer originate from the orthorhombic phase (o-phase) of the fluorite structure.

It can be seen that the thickness of the ferroelectric gate insulating layer (ZAO) is 41 nm. In addition, it can be seen that it has polycrystalline properties as it contains grains of various sizes, and grain growth was found not only in the bulk but also at the edges of the ferroelectric gate insulating layer (ZAO).

The size of nanocrystals included in the ferroelectric gate insulating layer (ZAO) is 5 nm to 15 nm.

In addition, it can be seen that the ZnO film used as an oxide semiconductor layer has a nanocrystalline structure with a distinct wurtzite phase.

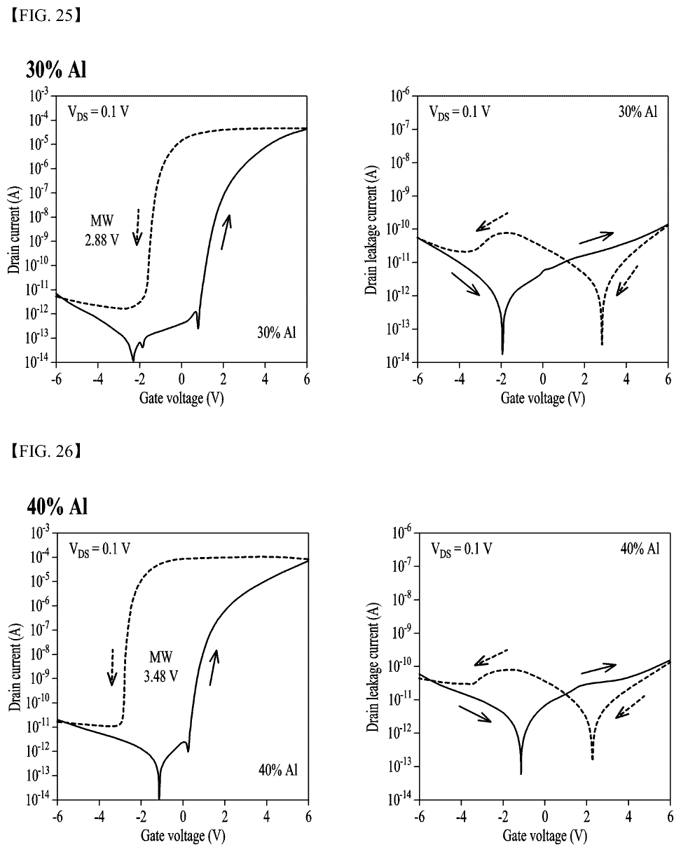

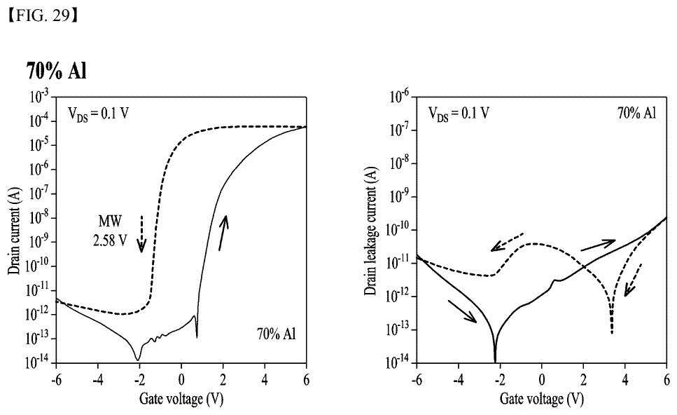

FIGS. 25 to 29 illustrate graphs of the hysteresis and gate leakage current characteristics of a ferroelectric thin film transistor according to an embodiment of the present disclosure including a ferroelectric gate insulating layer (ZAO) depending upon the molar concentration (Al doping percentage in ZAO) of Al.

Referring to FIGS. 25 to 29, the hysteresis behavior in a counterclockwise direction is exhibited, and the leakage current curve has a butterfly shape.

More particularly, referring to FIGS. 25 to 27, it can be seen that, as a result of the FE characteristics depending upon the Al content in AlZrOx, the MW increases as the Al content increases, so the properties are improved.

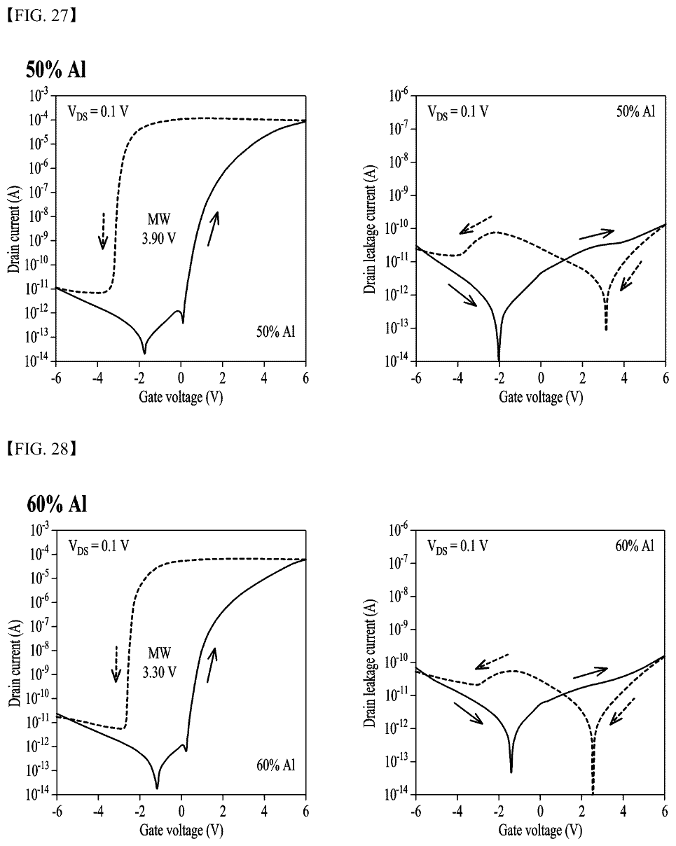

On the other hand, referring to FIGS. 27 to 29, it can be seen that MW is decreased when the Al content increases, so the properties are decreased. Therefore, when the Al content is 50%, the best properties are exhibited.

As apparent above, the present disclosure provides a ferroelectric ZAO compound capable of converting an amorphous ZAO compound to ferroelectric ZAO compound, ZrₓAl₁₋ₓO (x is 0.1 to 0.9), represented by Formula 1 by a crystalline oxide semiconductor compound containing nanocrystals, a method of preparing the same, a ferroelectric thin film transistor including the same and a method of manufacturing the ferroelectric thin film transistor.

Although the present disclosure has been described through limited examples and figures, the present disclosure is not intended to be limited to the examples. Those skilled in the art will appreciate that various modifications, additions and substitutions are possible, without departing from the scope and spirit of the disclosure. Therefore, it should be understood that there is no intent to limit the disclosure to the embodiments disclosed, rather, the disclosure is to cover all modifications, equivalents, and alternatives falling within the spirit and scope of the disclosure as defined by the claims.

What is claimed is:

1. A ferroelectric zirconium aluminum oxide (ZAO) compound, comprising:
zirconium; and
aluminum.

2. The ferroelectric ZAO compound according to claim 1, wherein the ferroelectric ZAO compound is represented by Formula 1 below:
ZrₓAl₁₋ₓO [Formula 1]
where x is 0.1 to 0.9.

3. A method of preparing a ferroelectric ZAO compound, the method comprising:
growing an amorphous ZAO compound on a substrate; and
growing a crystalline oxide semiconductor compound on the amorphous ZAO compound,
wherein in the growing of the crystalline oxide semiconductor compound, the amorphous ZAO compound is converted to a ferroelectric ZAO compound by the crystalline oxide semiconductor compound.

4. The method according to claim 3, wherein the ferroelectric ZAO compound is represented by Formula 1 below:
ZrₓAl₁₋ₓO [Formula 1]
where x is 0.1 to 0.9.

5. The method according to claim 3, wherein the growing of the amorphous ZAO compound is performed by spray pyrolysis.

6. The method according to claim 3, wherein the growing of the crystalline oxide semiconductor compound is performed by spray pyrolysis.

7. The method according to claim 3, wherein the crystalline oxide semiconductor compound comprises at least one of zinc oxide (ZnO), indium gallium zinc oxide (IGZO), indium oxide (InO), indium gallium oxide (IGO), indium aluminum oxide (IAO), indium zinc oxide (IZO), indium tin oxide (ITO), zinc tin oxide (ZTO), gallium zinc oxide (GZO), hafnium indium zinc oxide (HIZO), indium zinc tin oxide (IZTO) and aluminum zinc tin oxide (AZTO).

8. A ferroelectric thin film transistor, comprising:
a gate electrode formed on a substrate;
a gate insulating layer formed on the gate electrode;
an oxide semiconductor layer formed on the gate insulating layer; and
a source electrode and drain electrode respectively formed on opposite sides of the oxide semiconductor layer,
wherein the gate insulating layer comprises the ferroelectric zirconium aluminum oxide (ZAO) compound according to claim 1.

9. The ferroelectric thin film transistor according to claim 8, wherein the gate electrode comprises a first gate electrode and a second gate electrode.

10. The ferroelectric thin film transistor according to claim 8, wherein the gate insulating layer has a thickness of 30 nm to 60 nm.

11. The ferroelectric thin film transistor according to claim 8, wherein the oxide semiconductor layer contains nanocrystals.

12. The ferroelectric thin film transistor according to claim 8, wherein the oxide semiconductor layer has a thickness of 40 nm to 60 nm.

13. A method of manufacturing a ferroelectric thin film transistor, the method comprising:
forming a gate electrode on a substrate;
forming an amorphous gate insulating layer on the gate electrode;
forming a crystalline oxide semiconductor layer on the amorphous gate insulating layer; and
respectively forming a source electrode and drain electrode on opposite sides of the oxide semiconductor layer,
wherein, in the forming of the crystalline oxide semiconductor layer, the amorphous gate insulating layer is converted to a ferroelectric gate insulating layer by the crystalline oxide semiconductor layer.

14. The method according to claim 13, wherein the ferroelectric gate insulating layer comprises a ZAO compound represented by Formula 1 below:
ZrₓAl₁₋ₓO [Formula 1]
where x is 0.1 to 0.9.

15. The method according to claim 13, wherein the forming of the amorphous gate insulating layer is performed by spray pyrolysis.

16. The method according to claim 13, wherein the forming of the crystalline oxide semiconductor layer is performed by spray pyrolysis.
